(19) United States
(12) Patent Application Publication
(10) Pub. No.: US 2005/0008172 A1
(43) Pub. Date: Jan. 13, 2005

(54) APPARATUS AND METHOD FOR ELIMINATING NOISE

(76) Inventors: Yung-Liang LEE, Miao-Li County (TW); Yi-Jen HU, Miao-Li County (TW)

Correspondence Address: NAIPO (NORTH AMERICA INTERNATIONAL PATENT OFFICE), P.O. BOX 506, MERRIFIELD, VA, 22116, US

(21) Appl. No.: 10/710,372

(22) Filed: Jul. 6, 2004

(30) Foreign Application Priority Data
Jul. 11, 2003 (TW) 092119188

(51) Int. Cl. H04R 3/00; H03G 3/20

(52) U.S. Cl. 381/110; 381/120

(57) ABSTRACT

An apparatus and method for eliminating noise includes a power supply unit, a voltage monitoring circuit installed at the output of the power supply unit, a voice amplifier installed at the output of the voltage monitoring circuit and a speaker installed at the output of the voice amplifier. When a voltage is input from the power supply unit, the voltage monitoring circuit detects it and compares the value thereof with a default value, and then outputs a signal to control the voice amplifier; when the input voltage value is smaller than the default value, the voltage monitoring circuit outputs a control signal to shut off the voice amplifier; when the input voltage value is larger than the default value, the voltage monitoring circuit then outputs a control signal to turn on the voice amplifier, and the voice amplifier amplifies audio signals and the amplified audio signals are output as sounds through the speaker at the output thereof.

### BACKGROUND OF INVENTION

1. Field of the Invention

The present invention relates to an apparatus and method for eliminating noise, and more particularly to an apparatus and method for eliminating noise in a video device.

2. Description of the Prior Art

A speaker is often used in a general video device for outputting sounds. When a user once turns off the device not following a regular turning-off procedure, for example, when a user turns off power directly, noise is yielded owing to the sudden change of the electric power of a voice processing circuit or voice amplifying circuit. A sonic boom is sounded after the noise is outputted from the speaker to shock the user so that a hearing quality is lowered.

Please refer to FIG. 1. A conventional video device 10 for settling the sonic boom comprises a voice processing module 11, voice amplifier 12, relay 13 and speaker 14. Voice signals are amplified through the amplifier 12 after they are input into the voice processing module 11. And then, the voice signals are transmitted to the speaker 14 to output sounds through the relay 13 that is controlled to be driven by a DC power or AC power. The working principle of the relay 13 is that it is conductive when power is input and it is not conductive when power is not input. Such characteristic of the relay 13 is used to cut off the power of the relay 13 when the input power is turned off so that the sounds are not output through the speaker 14. Therefore, the sonic boom yielded from the improper shutoff of the power can be eliminated.

However, because elastic metal sheets are mainly used in the relay 13 for attaining electric conductivity and the elastic metal sheets are oxidized after time passes, the touch between the metal contacts of the elastic sheet becomes bad so that the problem concerning the failure rate of the relay appears. Besides, because the speaker 14 is driven by a large current, the chosen relay 13 matched therewith must be a large one. Therefore, the cost of the relay is higher.

### SUMMARY OF INVENTION

One object of the present invention is to provide an apparatus and method for eliminating noise, the noise yielded from the improper shutoff of power is eliminated through a voltage monitoring circuit.

Another object of the present invention is to provide an apparatus and method for eliminating noise, the default value of a voltage monitoring circuit can be adjusted according to the design of a product, and the flexibility in use and application range can further be enhanced.

Still another object of the present invention is to provide an apparatus and method for eliminating noise; a circuit control is used to reduce a failure rate so as to enhance the reliability of a product.

Still another object of the present invention is to provide an apparatus and method for eliminating noise; only a few electric parts are needed to constitute a voltage monitoring circuit such that a production cost can be reduced.

For attaining the objects mentioned above, an apparatus and method for eliminating noise according to the present invention comprises a power supply unit, a voltage monitoring circuit installed at the output of the power supply unit, a voice amplifier installed at the output of the voltage monitoring circuit and a speaker installed at the output of the voice amplifier. When a voltage is input from the power supply unit, the voltage monitoring circuit detects it and compares the value thereof with a default value, and then outputs a signal to control the voice amplifier; when the input voltage value is smaller than the default value, the voltage monitoring circuit outputs a control signal to shut off the voice amplifier; when the input voltage value is larger than the default value, the voltage monitoring circuit then outputs a control signal to turn on the voice amplifier, the voice amplifier amplifies audio signals and the amplified audio signals are output as sounds through the speaker at the output thereof.

### BRIEF DESCRIPTION OF DRAWINGS

The present invention can be more fully understood by reference to the following description and accompanying drawings, in which:

FIG. 1 is a block diagram, showing a conventional circuit from a voice input to a voice output in a video device of the prior art;

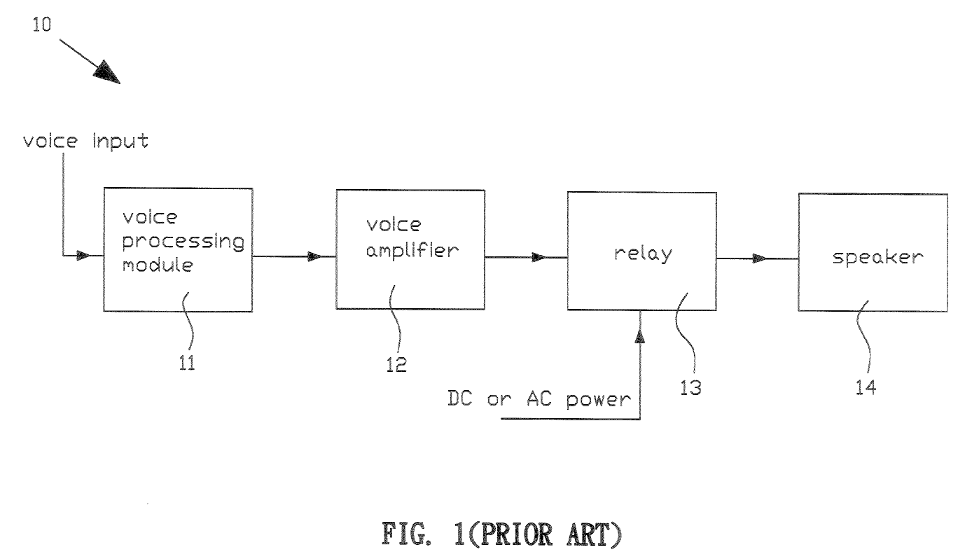

FIG. 2 is a block diagram, showing an apparatus for eliminating noise according to the present invention;

FIG. 3 is a flow chart, showing a method for eliminating noise according to the present invention; and

FIG. 4 is a circuit diagram, showing an internal circuit of a voltage monitoring circuit in an apparatus for eliminating noise according to the present invention.

### DETAILED DESCRIPTION

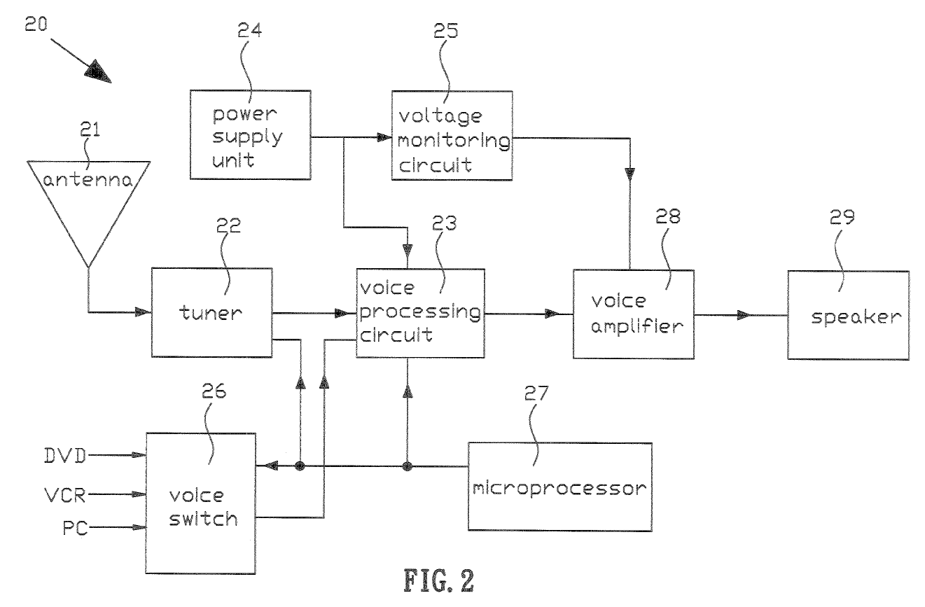

Please refer to FIG. 2. An apparatus for eliminating noise 20 comprises an antenna 21, tuner 22, voice processing circuit 23, power supply unit 24, voltage monitoring circuit 25, voice switch 26, microprocessor 27, voice amplifier 28, speaker 23. Video/audio signals are transferred to intermediate frequency signals that can be received by a television or demodulated to a video base frequency signals through the tuner 22 after high frequency video/audio signals are received by the antenna 21. And then, the output signals from the tuner 22 are input into the voice processing circuit 23 to separate into stereo and mono sounds so as to allow the audio signals to have multi-mode choices. Furthermore, the audio signals are amplified through the voice amplifier 28and then input into the speaker 29 to emit the audio signals as sounds. In addition, the voltage monitoring circuit 25 is connected to the voice amplifier 28 and used to send a control signal to open and close the voice amplifier 28. Because general municipal electricity only supplies AC power, the power supply unit 24 is needed to transfer AC power to DC power so as to drive the voice processing circuit 23, the voice amplifier 28 and the voltage monitoring circuit 25. Besides, different sound sources, such as digital video disk (DVD), video cassette recorder (VCR) and personal computer (PC), can also be received through the voice switch 26 in the apparatus 20 for eliminating noise; the sounds are received by the voice switch 26 and transmitted to the voice amplifier 28 to process amplification through the tuner 22 and voice processing circuit 23 and then output through the speaker 29. Furthermore, the software stored in the microprocessor 27 is used to control all hardware in the apparatus 20 for eliminating noise.

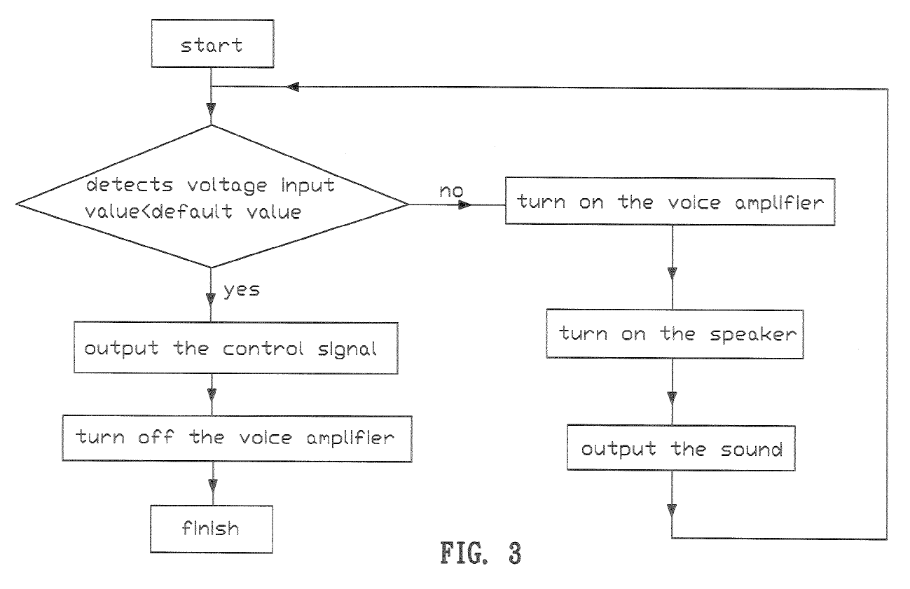

As to a method for eliminating noise, please refer to FIG. 3. First, after a voltage is input from the power supply unit 24, the voltage monitoring circuit 25 detects the value of the voltage input from the power supply unit 24, and then compares the voltage value, such as 4.5 volts, with a default value; when the input voltage value is greater than 4.5 volts, the turning-on of the voice amplifier 28 is maintained to allow the voice amplifier 28 to amplify audio signals and to transmit them to the speaker 29. Finally, the audio signals are output as sounds from the speaker 29.

Vice versa, when a user shuts off the power improperly, the sudden drop of the voltage is caused, the voltage monitoring circuit 25 will detect that the input voltage value is lower than the default value 4.5 volts. The voltage monitoring circuit will emit a control signal to close the voice amplifier 28 so as not to allow the noise or the pulses caused from the sudden declination of the voltage to be transmitted to the speaker 29 to output from it and further to prevent the sonic boom yielded from the improper shutoff of the AC power. The default voltage value of the voltage monitoring circuit 25 can be properly adjusted according to the design of each different product so that flexibility on application and a product application range can be increased.

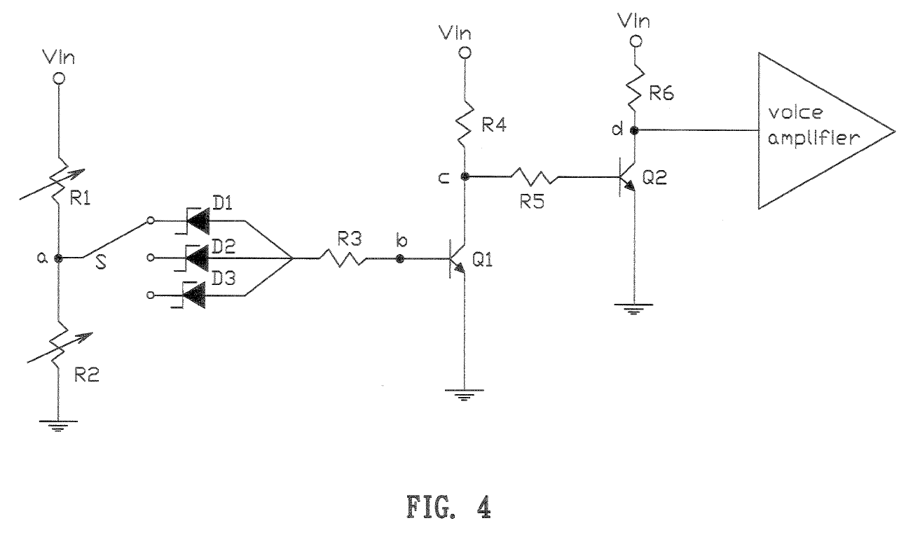

Please refer to FIG. 4. The voltage monitoring circuit 25 mainly comprises resistors R1 to R6, Zener diodes D1 to D3, switch device S and two transistors Q1 and Q2. A voltage divider circuit is constituted from the resistors R1 to R6, a voltage reference circuit is constituted from the switch device S, the zener diodes D1 to D3, the transistor Q1 and the resistors R3 and R4, and a control circuit is constituted from the resistors R5 and R6 and the transistor Q2. When the power supply unit 24 applies an input voltage Vᵢₙ, an output Vₐ at a voltage dividing nodal point a is decided through the voltage divider circuit, and the voltage Vₐ then passes through the voltage reference circuit. The zener diode D1, D2 or D3 is chosen by the switch device S to communicate with the voltage reference circuit. If the switch device S is connected to the zener diode D1, because the Voltage Vₐ is greater than the break down voltage of the zener diode D1, and the chosen resistor R3 is operated in coordination, the voltage V_{b} at a circuit nodal point bis greater than the communication voltage of the transistor Q1. At this time, the transistor Q1 is working at a saturation region, a voltage difference between the emitter and the collector of the transistor Q1 is a fixed value and very close to 0 volt. The voltage V_{c} at a reference voltage nodal point c is equal to the voltage difference between the emitter and the collector of the transistor Q1, V_{c} is lower than the conductive voltage of the transistor Q2, the transistor Q2 is not conducted. And then, the voltage of the control circuit Vᵢₙ is connected to the voice amplifier 28 through R6. Because the voltage V_{d} at a nodal point d of the control circuit is a little lower than Vᵢₙ, we design this voice amplifier 28 to receive the logic control signal of Vᵢₙ. This moment, the voltage V_{d} at the nodal point d is “High” to the voice amplifier 28 so that the voice amplifier 28 is then turned on.

When the input voltage Vᵢₙ applied by the power supply unit 24 is lowered, the voltage Va is passed through the break down voltage of the zener diode and the voltage drop of the resistor R3 to cause the voltage V_{b} at the circuit nodal point b to be smaller than the conductive voltage of the transistor Q1 and cause the transistor not to be conducted so that the voltage V_{c} at the nodal point c become a little smaller than the voltage of Vᵢₙ, this voltage is still greater than the conductive voltage of the transistor Q2 to allow the transistor Q2 to work at a saturation region. The voltage difference between the collector and the emitter of the transistor Q2 is a fixed value and is very close to 0 volt to cause the voltage V_{d} at the nodal point d to be equal to the voltage difference, this voltage value V_{d} is “Low” to the voice amplifier 28 so that the voice amplifier 28 is turned off.

Using the characteristic of the voltage monitoring circuit 25, when an input voltage value is once lower than a default value, the voice amplifier 28 can be shut off immediately to prevent the noise yielded from such kind of improper shutoff of AC power from outputting to the speaker 29 through the voice amplifier 28 to lower a hearing quality. The voltage monitoring circuit 25 can be designed according to a different product. The switch device S is used to choose the different zener diodes D1 to D3 so as to choose different reference voltages, and the tolerance between the voltage Vₐ and the reference voltage can be changed by adjusting the variable R1 and R2, so, it is very flexible in use. Of the same reason, the voltage monitoring circuit 25 mentioned above can also form an integrated circuit (IC) to attain a voltage monitoring function. The voltage monitoring circuit 25 according to the present invention only needs a several electronic elements or an integrated circuit to attain a voltage monitoring function, it is much cheaper than a large relay used in the prior art so that a production cost can further be reduced.

It is noted that the apparatus and method for eliminating noise described above is the preferred embodiment of the present invention for the purpose of illustration only, and are not intended as a definition of the limits and scope of the invention disclosed. Any modifications and variations that may be apparent to a person skilled in the art are intended to be included within the scope of the present invention.

1. A method for eliminating noise, wherein video/audio signals are transmitted to a voice processing circuit, and then said video/audio signals are outputted to a speaker through a voice amplifier, said method comprising:
(1)inputting a voltage to said voice processing circuit form a power supply unit;
(2)using a voltage monitoring circuit to detect said input voltage and compare said input voltage with a default value; and
(3)outputting a control signal to shut off said voice amplifier when said voltage value is smaller than said default value.

2. The method for eliminating noise according to claim 1, wherein said voice amplifier is maintained turned on when said input voltage greater than said default value.

3. The method for eliminating noise according to claim 1, wherein said default value can be adjusted according to a product.

4. The method for eliminating noise according to claim 1, further comprising a step: receiving said video/audio signals through a tuner.

5. The method for eliminating noise according to claim 1, further comprising a step: receiving said video/audio signals from different sources through a voice switch.

6. A noise eliminating apparatus, comprising:
a voice processing circuit for processing and receiving video/audio signals;
a voice amplifier for amplifying audio signals of said voice processing circuit;
at least one speaker for outputting said amplified audio signal;
a power supply unit for providing a input voltage to said voice processing circuit; and
a voltage monitoring circuit, installed at an output of said power supply unit and used for detecting said input voltage from said power supply unit to control the on and off of said voice processing circuit.

7. The noise eliminating apparatus according to claim 6, further comprising a tuner for receiving video/audio signals and then inputting said signals into said voice processing circuit.

8. The noise eliminating apparatus according to claim 6, further comprising a voice switch for receiving video/audio signals from different sources and then inputting said signals into said voice processing circuit.

9. The noise eliminating apparatus according to claim 6, wherein said voltage monitoring circuit has an adjustable default voltage value used for a comparison standard to said input voltage from said power supply unit.

10. The noise eliminating apparatus according to claim 9, wherein said voltage monitoring circuit shuts off said voice processing circuit when said input voltage is smaller than said default value.

11. A voltage monitoring circuit, comprising:
a voltage dividing circuit, comprising a plurality of resistors for deciding a default voltage value output from a voltage dividing nodal point;
a voltage reference circuit, connected to said voltage dividing nodal point and having at least one zener diode, a transistor being controlled by the voltage of said zener diode to form a reference voltage of said nodal point of said voltage reference circuit;
a control circuit, connected to a nodal point of said voltage reference circuit, controlling another transistor to output a high or low voltage.

12. The voltage monitoring circuit according to claim 11, wherein said resistors have at least one variable resistor.

13. The voltage monitoring circuit according to claim 11, wherein said voltage reference circuit consists of a switch device for switching said zener diode.

14. The voltage monitoring circuit according to claim 11, wherein a resistor is connected behind said zener diode.

15. The voltage monitoring circuit according to claim 11, wherein said control circuit outputs a high or low voltage to a voice amplifier.

16. The voltage monitoring circuit according to claim 11, wherein said control circuit comprises at least one resistor.
